(19) United States
(12) Patent Application Publication
(10) Pub. No.: US 2020/0027174 A1
(43) Pub. Date: Jan. 23, 2020

(54) ELECTRICITY CONSUMPTION METER WITH PIGGY BACKED E-COMMERCE SYSTEM AND METHOD

(71) Applicant: RYNAN TECHNOLOGIES PTE. LTD., SINGAPORE (SG)

(72) Inventors: MY T. NGUYEN, TRA VINH CITY, TRA VINH PROVINCE (VN); LUONG V. TRUONG, CHAU THANH DISTRICT, TRA VINH PROVINCE (VN); CUONG Q. HONG, TRA VINH CITY, TRA VINH PROVINCE (VN); BIEN T. THU MAI, CAU KE DISTRICT, TRA VINH PROVINCE (VN); AN TRINH, TRA VINH CITY, TRA VINH PROVINCE (VN); TRIEU T. LE, HON DAT DISTRICT, KIEN GIANG PROVINCE (VN); THONG A. NGUYEN, TRA VINH CITY, TRA VINH PROVINCE (VN); KHANG M. DUONG, CAN THO CITY (VN)

(21) Appl. No.: 16/498,114

(22) PCT Filed: Mar. 26, 2018
(86) PCT No.: PCT/CA2018/050360

§ 371 Date: Sep. 26, 2019

Related U.S. Application Data
(60) Provisional application No. 62/477,569, filed on Mar. 28, 2017.

(51) Int. Cl. G06Q 50/06; G06Q 30/06; G01R 22/06

(52) U.S. Cl. CPC G06Q 50/06; G01R 22/063; G06Q 30/0641

(57) ABSTRACT

An electricity consumption meter with piggy backed e-commerce is disclosed wherein a wide area network (WAN) and an application on a smartphone or the like can be used to retrieve a measured electricity consumption from an electricity consumption meter while accessing an e-commerce system. The application displays the retrieved electricity consumption together with at least one product, and further wherein the at least one product may be purchased from the e-commerce system using the application.

### FIELD OF THE INVENTION

The present invention relates to an electricity consumption meter with piggy backed e-commerce system and method.

### BACKGROUND TO THE INVENTION

In order to monitor the use of electricity, electricity consumption meters have been installed in buildings and residences. One drawback is that the most common of such meters, known as electromechanical induction watt-hour meters, may only be read manually. Installation of electronic meters that can transmit readings remotely is expensive for both the utilities, who wish to have an accurate view of actual consumption, and for users, who better wish to understand their own consumption as well as the costs involved.

### SUMMARY OF THE INVENTION

In order to address the above, there is provided an electricity consumption metering system with piggy backed e-commerce. The system comprises an electricity utility comprising an electricity consumption data collection server comprising circuitry for communicating via a Wide Area Network (WAN), an e-commerce system selling at least one product and comprising circuitry for communicating via the WAN, an electricity transmission system comprising transmission lines supplying electricity to a plurality of locations of electricity consumption, a plurality of electricity consumption meters, one of the electricity consumption meters attached along the transmission lines at each of the locations of electricity consumption, each of the electricity consumption meters comprising a meter for measuring electricity consumption, circuitry for communicating via a near field network, circuitry for communicating via the wide area network and a controller. The measured electricity consumption is transferred from time to time to the electricity consumption data collection server via the wide area network, and a plurality of hand held user devices each comprising circuitry for communicating via the wide area network and an application for communicating with an accessible one of the electricity consumption meters using the wide area network, wherein, using the wide area network, the application retrieves the measured electricity consumption of the accessible electricity consumption meter and accesses the e-commerce system via the wide area network, the application displaying the retrieved electricity consumption together with the at least one product, and further wherein the at least one product may be purchased from the e-commerce system using the application.

There is also disclosed an electricity meter for measuring consumption of electricity provided from a utility via a transmission line to a consumer system, the utility comprising an electricity consumption data collection server accessible via a Wide Area Network (WAN). The meter comprises an input for attachment to the transmission line, an output for attachment to the consumer system, a real time clock, a voltage sensor for measuring from time to time a voltage at a point of connection between the transmission line and the consumer system, a current sensor for measuring from time to time a current flowing between the transmission line and the transmission line, a processor for calculating a present energy consumption from the measured voltage and the measured current, a memory for storing from time to time at least the measured voltage and the measured current together with a time stamp, a display for displaying at least the present energy consumption, and a communication module comprising nearfield network circuitry for transmitting the measured voltage and the measured current to a hand held device and a WAN circuitry for transmitting from time to time the measured voltage and the measured current to the data collection server.

Additionally, there is disclosed a method for providing an electricity consumption metering system with piggy backed e-commerce. The method comprises attaching each of a plurality of electricity consumption meters at a respective consumer location along transmission lines of an electricity transmission system, the transmission lines supplying electricity to a plurality of consumers, measuring a consumer electricity consumption at each of the respective consumer locations, transmitting from time to time the measured consumer electricity consumption to a data collection server via a Wide Area Network (WAN), retrieving the consumer electricity consumption of the given consumer using a handheld device, and displaying the consumer electricity consumption of the given consumer on the consumer's device together with a product from an e-commerce system selling a plurality of different products.

### BRIEF DESCRIPTION OF THE DRAWINGS

FIG. 1 provides a schematic diagram of an electricity consumption meter with piggy backed e-commerce in accordance with an illustrative embodiment of the present invention;

FIG. 2 provides a schematic diagram of an electricity consumption meter in accordance with an illustrative embodiment of the present invention; and

FIGS. 3A through 3I provide screen grabs of a combined electricity consumption/e-commerce application in accordance with an illustrative embodiment of the present invention.

### DETAILED DESCRIPTION OF THE ILLUSTRATIVE EMBODIMENTS

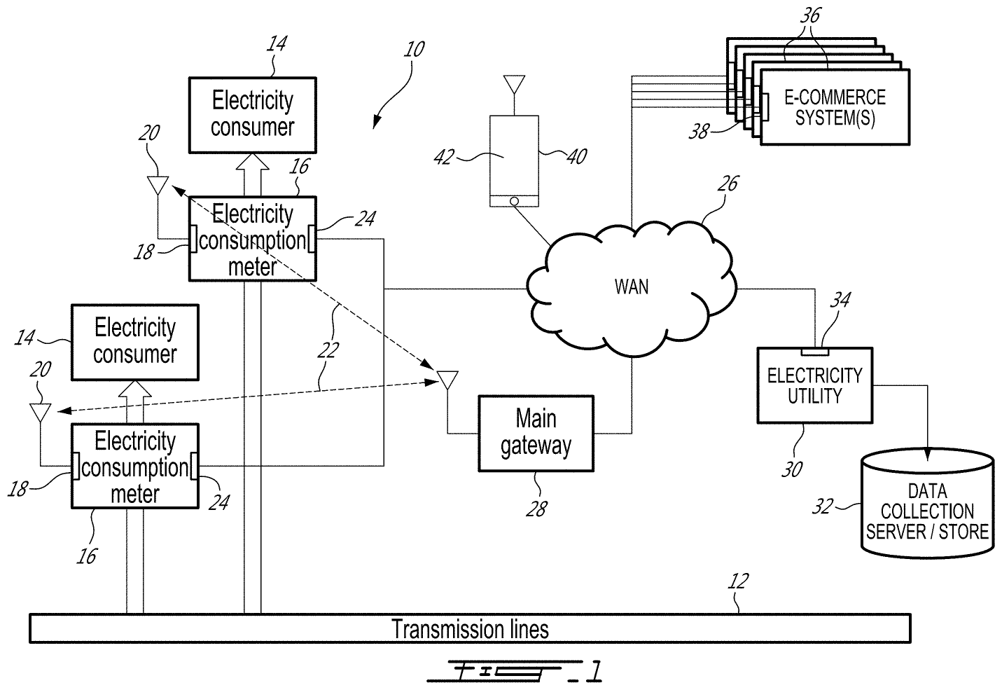

Referring now to FIG. 1, an electricity consumption meter with piggy backed e-commerce, and generally referred to using the reference numeral 10, will now be described. A transmission line 12 provides electricity to a plurality of electricity consumers 14 at a location of electricity consumption, such as a residence, building or business or the like (not shown) via a respective electricity consumption meter 16. Each electricity consumption meter may comprise network circuitry 18, for example a nearfield network such as RF or Bluetooth and/or WiFi, including an associated antenna 20 for communicating via an RF/Bluetooth/WiFi LAN 22 and wide area network circuitry 24 for communicating via a Wide Area Network (WAN) 26 such as the internet or like. In this regard, the WAN circuitry can include for example a cellular modem (not shown) for accessing the WAN 26 via a GSM/GPRS/GPS type connection. In an alternative embodiment, access to the WAN 26 is provided to the plurality of electricity consumption meters (for example in multi-unit housing or the like) via the RF/Bluetooth/WiFi LAN 22 and a main gateway 28.

Still referring to FIG. 1, an electricity utility 30 comprising an electricity consumption data collection server and a data store 32 and wide area network circuitry 34 for communicating via the WAN 26 is interconnected to the electricity consumption meters 16 via the WAN 26, to which are also attached at least one e-commerce system 36, also comprising wide area network circuitry 38 for communicating via the WAN 26, and selling products (not shown). A plurality of hand held devices 40, such as a smartphone or tablet or the like, each executing an application 42, communicate with an accessible one of the electricity consumption meters 16 via the WAN 26.

Still referring to FIG. 1, the electricity utility 30 collects from time to time data on electricity consumption from the electricity consumption meter 16 via the WAN 26. This data may be stored in the data store 32 for analysis purposes and billing and the like. Additionally, a user may access a local electricity consumption meter 16 using a suitably equipped hand held device 40 including the application 42 and via the WAN 26 to retrieve information on local electricity consumption from the electricity consumption meter 16.

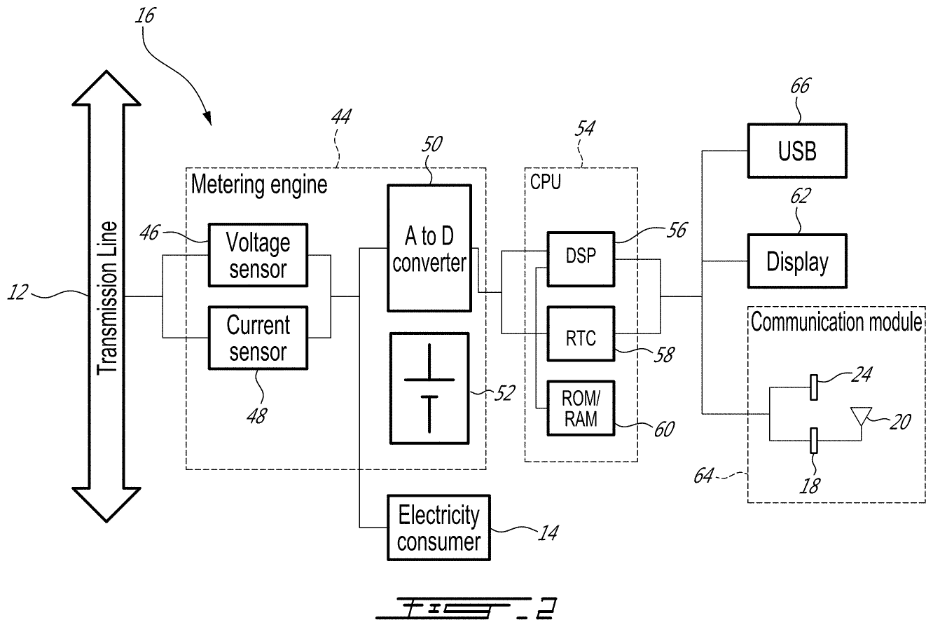

Referring now to FIG. 2 in addition to FIG. 1, an illustrative embodiment of an electricity consumption meter 16 is provided, comprising a metering engine 44 comprising a voltage sensor 46, a current sensor 48, an Analog to Digital converter (A to D converter) 50 and a backup battery 52, a microcontroller (CPU) 54 comprising a digital signal processor (DSP) 56, a real-time clock (RTC) 58 and a memory 60, a display 62, a communication module 64, and a physical interface 66. As the transmission line 12 feeds current and voltage into the metering engine 44 before arriving at the electricity consumer 14, the voltage sensor 46 and current sensor 48 respectively measure current and voltage and output their respective results to the A to D converter 50. The included backup battery 52 may allow the metering engine 44 to remain active when transmission line 12 is not feeding power to the metering engine 44. The A to D converter 50 then outputs a digital signal to the CPU 54, where the DSP 56 calculates various desired metering parameters, such as energy consumption, in association with data provided by the RTC 58. The desired metering parameters are stored inside the memory 60 for backup and future consultation purposes, and then fed to the display 62 where they may be viewed by a user. The desired metering parameters are also fed to the communications module 64, which may comprise the above-mentioned network circuitry 18, associated antenna 20, and wide area network circuitry 24, so that the parameters may be sent to the electricity utility 30 for consumption evaluation purposes and to ensure accurate billing. Further, the physical interface 66, for example a USB or Serial port, allows the recorded metering parameters to be read by the handheld device 40 if the communications module 64 is unavailable.

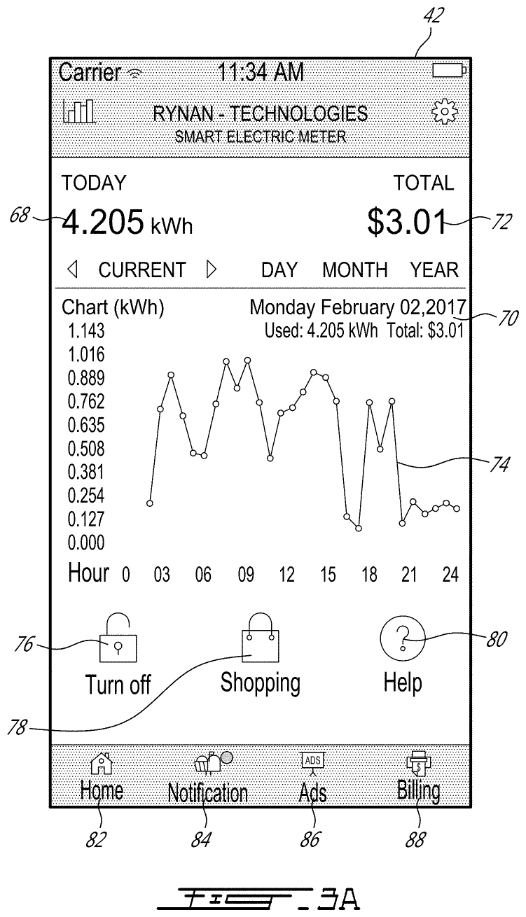

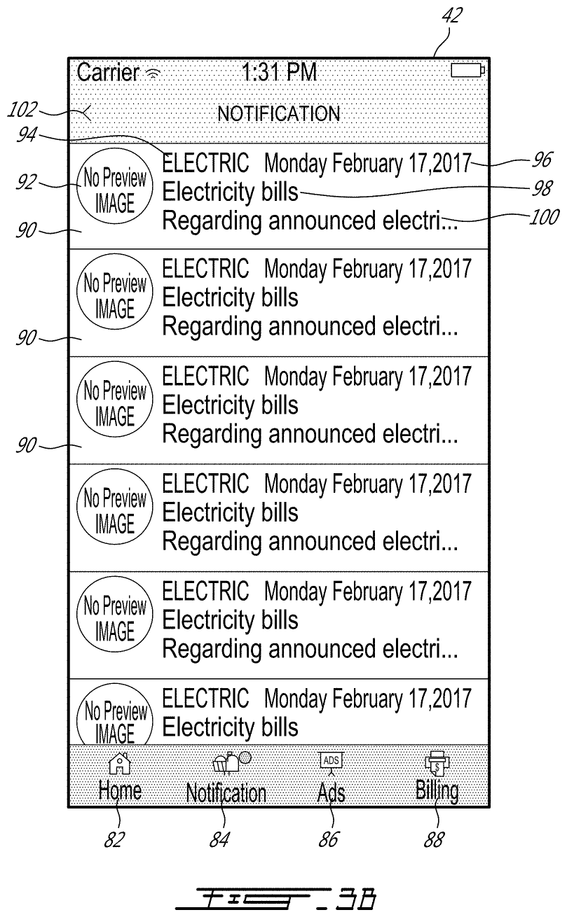

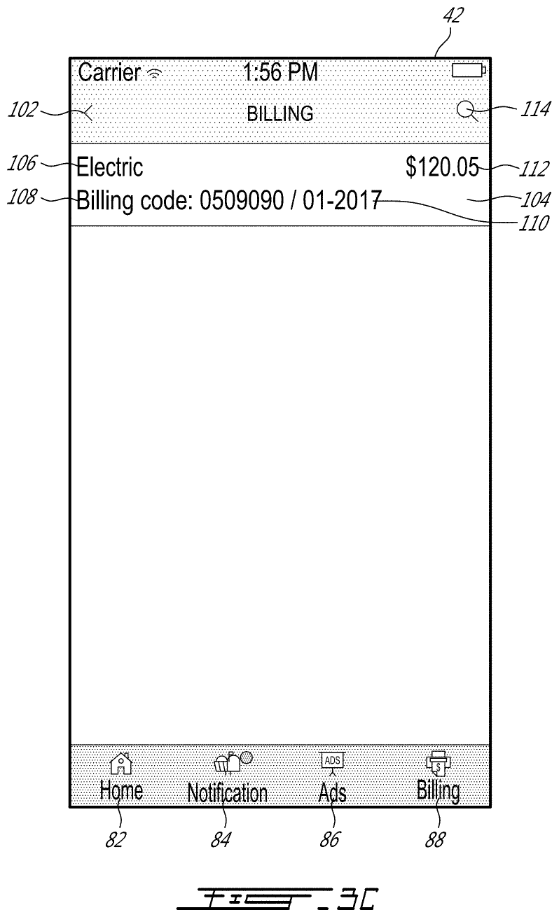

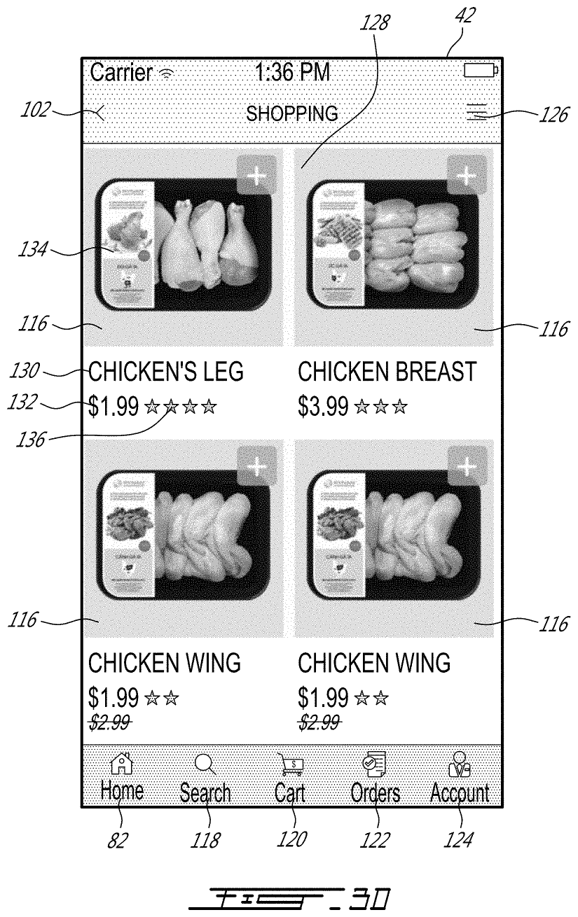

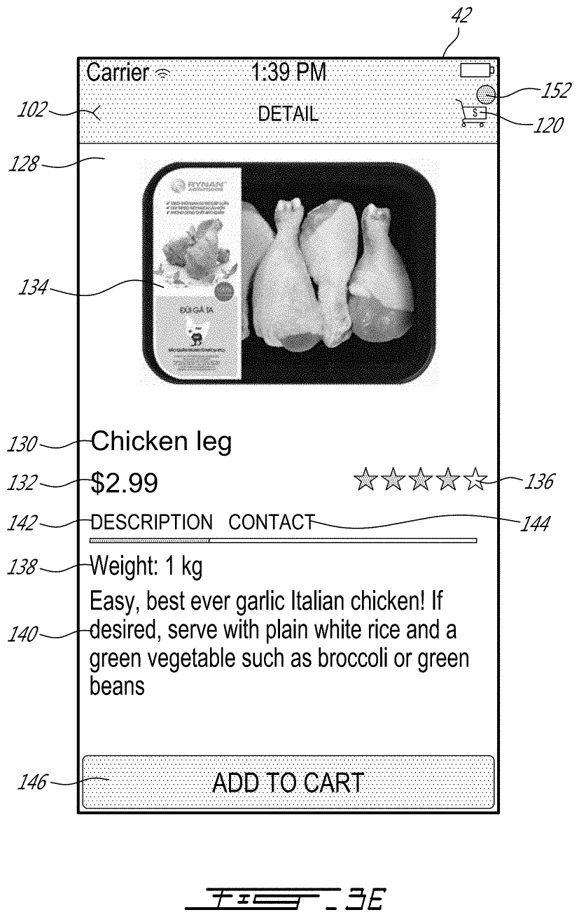

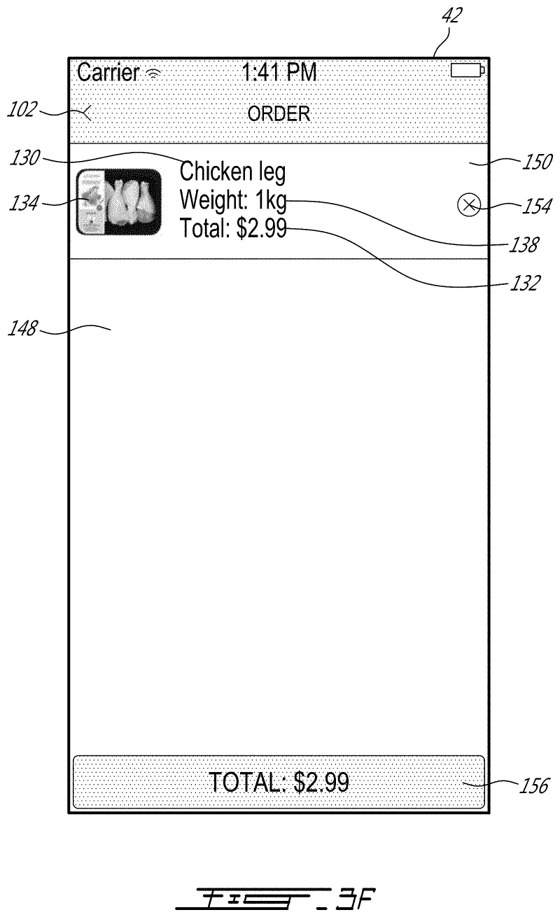

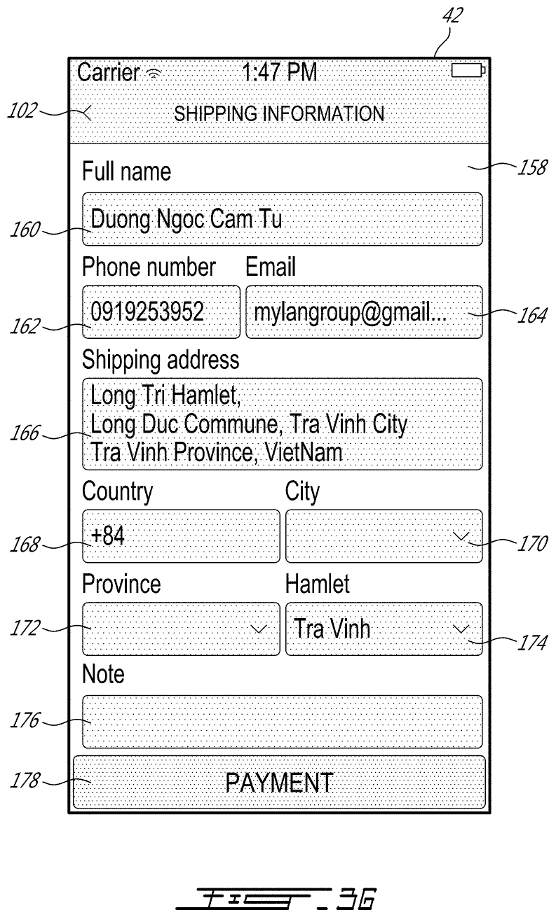

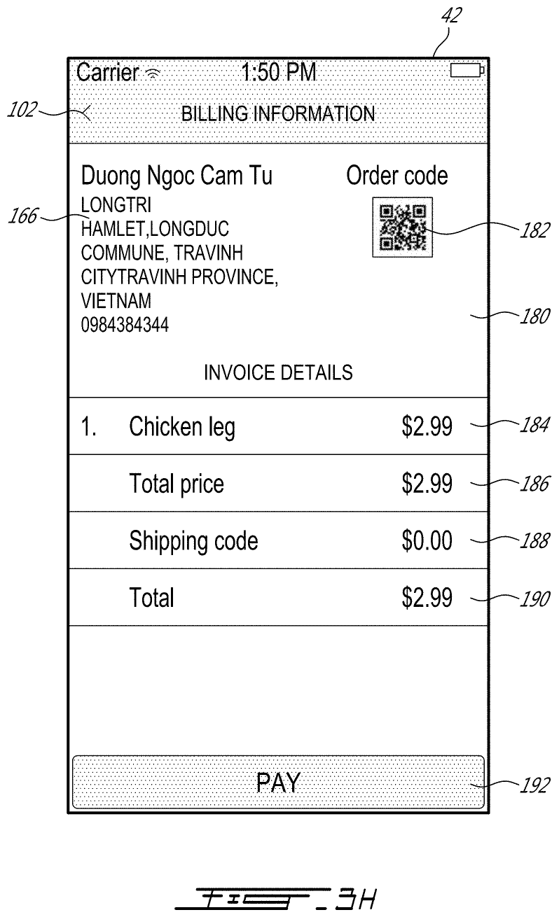

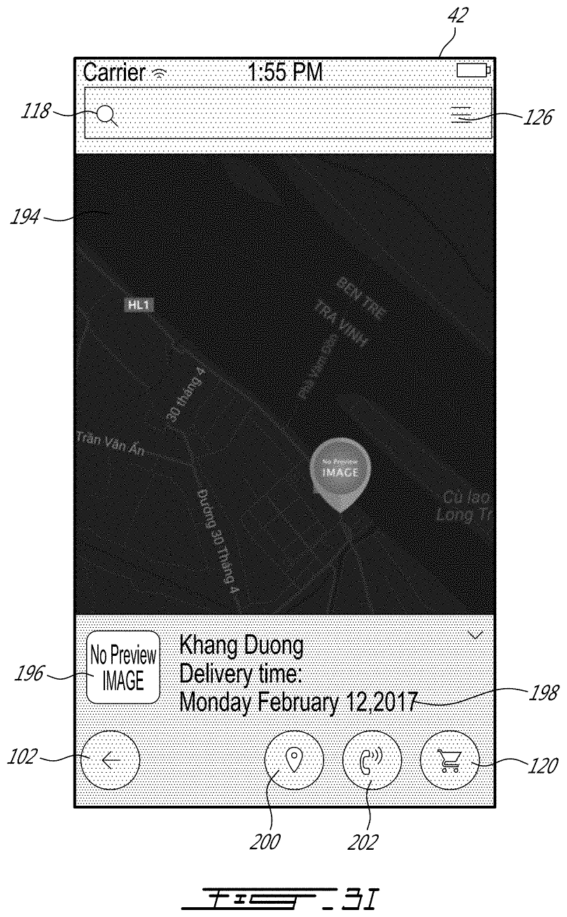

Referring now to FIG. 3A in addition to FIG. 1, as discussed above the hand held user device 40 comprises an application 42 for displaying electricity consumption 68, for example for a given day 70 and including the amount 72 the utility will charge for the electricity use. Diagnostic charts 74 and other graphics may be provided to aid the user in understanding their electricity consumption over the selected period of time. Icons for turning off the application 76, entering the e-commerce shopping system 78, and asking for help 80 may be provided. Further, users may migrate through various pages of the application 42 by selecting icons for the home screen 82, notification list 84, advertisements 86 and billing information 88.

Referring now to FIG. 3B in addition to FIG. 3A, upon selecting the notification icon 84, the application 42 displays a list of notifications 90. Illustratively, a notification 90 may comprise a preview image 92, a sender's name 94, a notification date 96, a notification title 98, and a notification text preview 100. Upon selection of a notification 90, the application 42 displays the notification text in its entirety (not shown). Upon selecting a back button 102, the application 42 returns to the previous screen.

Referring now to FIG. 3C in addition to FIG. 3A, upon selecting the billing icon 88, the application 42 displays a summary of the most recent invoice 104 comprising an invoice title 106, billing code 108, billing month 110 and invoice cost 112. Upon selecting the invoice 104, a detailed invoice may be displayed (not shown). In addition, a search icon 114 allows a user to search through previous invoices 104.

Referring now to FIGS. 3D to 3I in addition to FIGS. 1 and 3A, upon selecting the shopping icon 78, the user is brought to the e-commerce system 36. Icons listing products 116 available from the e-commerce system 36 are displayed, thereby providing the user with convenient access to the e-commerce system 36. Icons for searching for products 118, viewing products previously added to a virtual shopping cart 120, viewing a list of orders 122, viewing a user's account information 124, and browsing additional menu options 126 may also be provided.

Still referring to FIGS. 3D to 3I, upon selecting a product icon 116, the application 42 displays a product detail page 128 that may provide various product details such as product title 130, product price 132, product image 134, average crowd-sourced product review rating 136, product weight 138, and product description 140. Icons for migrating between the item description page 142 and the seller's contact information 144 may also be provided. Upon selecting the add to cart icon 146, the application 42 displays an order page 148 comprising a list of selected items 150. Alternatively, the virtual shopping cart icon 120 may display an indicator 152 indicating that one or more items have already been selected. Upon selecting the remove item icon 154, the selected item 150 is removed from the list of selected items 150, if so desired. Alternatively, upon selecting the icon displaying the total price 156, the application 42 displays a shipping information page 158.

Still referring to FIGS. 3D to 3I, the shipping information page 158 may comprise text fields for entering various user information such as full name 160, phone number 162, email address 164, shipping address 166, shipping country 168, shipping city 170, shipping state or province 172, city subdivision 174, illustratively borough, district or hamlet, as well as a field for various notes 176. Upon selecting the payment icon 178, the application 42 displays a billing information screen 180. The billing information screen 180 may comprise the above-entered shipping address 166, order code 182, illustratively a QR code, and invoice details such as item title and price 184, price of all selected items 186, shipping cost 188, and final price 190. Advantageously, the user may have previously stored their payment information, illustratively credit card information, in a payment information field (not shown) accessed through the account information icon 124. Thus, selecting the pay icon 192 would send the order to the seller as well as pay for the order using the user's payment information.

Referring now to FIG. 3I, the application 42 may display a shipment tracking page 194, illustratively a map-based page, displaying a preview image 196 and estimated delivery time 198. The shipment tracking page 194 may also present a user locating icon 200, as well as a seller calling icon 202, allowing the user to contact the seller for further information and inquiries.

Although the present invention has been described hereinabove by way of specific embodiments thereof, it can be modified, without departing from the spirit and nature of the subject invention as defined in the appended claims.

We claim:

1. An electricity consumption metering system with piggy backed e-commerce, comprising:
an electricity utility comprising an electricity consumption data collection server comprising circuitry for communicating via a Wide Area Network (WAN);
an e-commerce system selling at least one product and comprising circuitry for communicating via said WAN;
an electricity transmission system comprising transmission lines supplying electricity to a plurality of locations of electricity consumption;
a plurality of electricity consumption meters, one of said electricity consumption meters attached along said transmission lines at each of said locations of electricity consumption, each of said electricity consumption meters comprising a meter for measuring electricity consumption, circuitry for communicating via a near field network, circuitry for communicating via said wide area network and a controller, wherein said measured electricity consumption is transferred from time to time to said electricity consumption data collection server via said wide area network; and
a plurality of hand held user devices each comprising circuitry for communicating via said wide area network and an application for communicating with an accessible one of said electricity consumption meters using said wide area network;
wherein, using said wide area network, said application retrieves said measured electricity consumption of said accessible electricity consumption meter and accesses said e-commerce system via said wide area network, said application displaying said retrieved electricity consumption together with said at least one product, and further wherein said at least one product may be purchased from said e-commerce system using said application.

2. The electricity consumption metering system of claim 1, wherein said near field network is provided by one of Bluetooth, RF and WiFi.

3. The electricity consumption metering system of claim 1, wherein said WAN comprises a GSM/GPRS/GPS network.

4. The electricity consumption metering system of claim 1, said plurality of electricity consumption meters each further comprising a back-up battery.

5. The electricity consumption metering system of claim 4, said plurality of electricity consumption meters each further comprising a memory for storing said measured electricity consumption and a physical interface and further wherein a contents of said memory can be read via said physical interface.

6. The electricity consumption metering system of claim 5, wherein said physical interface is a USB interface.

7. The electricity consumption metering system of claim 5, further comprising a main gateway interconnecting a plurality of said electricity consumption meters with said WAN.

8. The electricity consumption metering system of claim 7, wherein said main gate way is connected to said WAN using a GSM/GPRS/GPS network.

9. The electricity consumption metering system of claim 7, wherein each of said electricity consumption meters is connected to said main gate way using a near field network.

10. An electricity meter for measuring consumption of electricity provided from a utility via a transmission line to a consumer system, the utility comprising an electricity consumption data collection server accessible via a Wide Area Network (WAN), the meter comprising:
an input for attachment to the transmission line;
an output for attachment to the consumer system;
a real time clock;
a voltage sensor for measuring from time to time a voltage at a point of connection between the transmission line and the consumer system;
a current sensor for measuring from time to time a current flowing between the transmission line and the transmission line;
a processor for calculating a present energy consumption from said measured voltage and said measured current;
a memory for storing from time to time at least said measured voltage and said measured current together with a time stamp;
a display for displaying at least said present energy consumption; and
a communication module comprising nearfield network circuitry for transmitting said measured voltage and said measured current to a hand held device and a WAN circuitry for transmitting from time to time said measured voltage and said measured current to the data collection server.

11. The electricity meter of claim 10, wherein said present energy consumption is transmitted from time to time to the data collection server.

12. The electricity meter of claim 10, wherein said present energy consumption is transmitted from time to time to the hand held device.

13. The electricity meter of claim 12, wherein the hand held device comprises a smartphone.

14. The electricity meter of claim 10, wherein the transmission line and the consumer system terminate at a standard watthour meter socket and further comprising a housing compatible with said standard watthour meter socket.

15. A method for providing an electricity consumption metering system with piggy backed e-commerce, comprising:
attaching each of a plurality of electricity consumption meters at a respective consumer location along transmission lines of an electricity transmission system, said transmission lines supplying electricity to a plurality of consumers;
measuring a consumer electricity consumption at each of said respective consumer locations;
transmitting from time to time said measured consumer electricity consumption to a data collection server via a Wide Area Network (WAN);
retrieving said consumer electricity consumption of the given consumer using a handheld device; and
displaying said consumer electricity consumption of the given consumer on said consumer's device together with a product from an e-commerce system selling a plurality of different products.

16. The method of claim 15, wherein said retrieving comprises running an application on said device, said application configured for retrieving said consumer electricity consumption of the given consumer from said data collection server.

17. The method of claim 15, wherein said retrieving comprises running an application on said device, said application configured for retrieving said consumer electricity consumption of the given consumer from a consumer one of said electricity consumption meters.
